(19) United States
(12) Patent Application Publication
(10) Pub. No.: US 2026/0198077 A1
(43) Pub. Date: Jul. 9, 2026

(54) SEMICONDUCTOR DEVICES COMPRISING DIELECTRIC WALL STRUCTURES

(71) Applicant: SAMSUNG ELECTRONICS CO., LTD., Suwon-si (KR)

(72) Inventors: Hyohoon Byeon, Suwon-si (KR); Gyeom Kim, Suwon-si (KR); Seokhoon Kim, Suwon-si (KR); Yongjun Nam, Suwon-si (KR); Pankwi Park, Suwon-si (KR)

(73) Assignee: SAMSUNG ELECTRONICS CO., LTD., Suwon-si (KR)

(21) Appl. No.: 19/427,003

(22) Filed: Dec. 19, 2025

(30) Foreign Application Priority Data
Jan. 7, 2025 (KR) 10-2025-0002088

(51) Int. Cl. H10D 84/83; H10D 84/01

(52) U.S. Cl. CPC H10D 84/833; H10D 84/0151

(57) ABSTRACT

A semiconductor device includes a substrate including an active region extending in a first direction, a gate structure on the substrate and extending in a second direction intersecting the first direction, a plurality of channel layers on the active region, spaced apart from each other in a third direction perpendicular to an upper surface of the substrate, and surrounded by the gate structure, a dielectric wall structure on one side of the active region, extending in the first direction and penetrating the gate structure, a first epitaxial pattern on a side surface of the dielectric wall structure and connected to the plurality of channel layers, a second epitaxial pattern on the first epitaxial pattern, and a third epitaxial pattern surrounding side surfaces and an upper surface of the second epitaxial pattern in the second direction.

### CROSS-REFERENCE TO RELATED APPLICATION(S)

This application is based on and claims priority to Korean Patent Application No. 10-2025-0002088, filed on Jan. 7, 2025, in the Korean Intellectual Property Office, the disclosure of which is incorporated by reference herein in its entirety.

### BACKGROUND

The present disclosure relates to a semiconductor device.

As the demand for high performance, high speed, and/or multifunctionality of semiconductor devices increases, a degree of integration of semiconductor devices is increasing. In order to manufacture semiconductor devices with fine patterns in response to the trend for high integration of semiconductor devices, implementing patterns having fine widths or fine separation distances may be required. In addition, efforts are being made to develop semiconductor devices including fin field effect transistors (FinFETs) having a three-dimensional channel structure in order to overcome the limitations of operating characteristics due to the size reduction of planar metal oxide semiconductor (MOS) FETs (MOSFETs).

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device that may be capable of improved integration and reliability.

Additional aspects will be set forth in part in the description which follows and, in part, will be apparent from the description, or may be learned by practice of the presented embodiments.

According to an aspect of an example embodiment, a semiconductor device may include a substrate including an active region extending in a first direction, a gate structure on the substrate and extending in a second direction intersecting the first direction, a plurality of channel layers on the active region, spaced apart from each other in a third direction perpendicular to an upper surface of the substrate, and surrounded by the gate structure, a dielectric wall structure on one side of the active region, extending in the first direction and penetrating the gate structure, a first epitaxial pattern on a side surface of the dielectric wall structure and connected to the plurality of channel layers, a second epitaxial pattern on the first epitaxial pattern, a third epitaxial pattern surrounding side surfaces and an upper surface of the second epitaxial pattern in the second direction, a silicide pattern surrounding side surfaces and an upper surface of the third epitaxial pattern in the second direction, and a metal pattern surrounding side surfaces and an upper surface of the silicide pattern in the second direction, where the third epitaxial pattern, the silicide pattern, and the metal pattern are between the second epitaxial pattern and the dielectric wall structure.

According to an aspect of an example embodiment, a semiconductor device may include a substrate, a dielectric wall structure on the substrate and extending in a first direction, active regions extending in the first direction and on both side surfaces of the dielectric wall structure in a second direction intersecting the first direction, a gate structure on the substrate and extending in the second direction, where the dielectric wall structure intersects the gate structure, a plurality of channel layers on at least one of the active regions, spaced apart from each other in a third direction perpendicular to an upper surface of the substrate, and surrounded by the gate structure, source/drain regions on at least one side of the gate structure, on both side surfaces of the dielectric wall structure in the second direction, and connected to the plurality of channel layers, and a metal pattern surrounding both side surfaces and an upper surface of the source/drain regions in the second direction, where the dielectric wall structure includes an inner dielectric wall, and an outer dielectric wall surrounding a portion of a side surface and a lower surface of the inner dielectric wall that is adjacent to the metal pattern in the second direction, side surfaces of the outer dielectric wall in the second direction contact the active regions, and the outer dielectric wall includes regions adjacent to the source/drain regions in the third direction.

According to an aspect of an example embodiment, a semiconductor device may include a substrate, a dielectric wall structure on the substrate and extending in a first direction, a gate structure on the substrate and extending in a second direction that intersects the first direction, where the dielectric wall structure intersects the gate structure, a plurality of channel layers spaced apart from each other in a third direction perpendicular to an upper surface of the substrate, and on both sides of the dielectric wall structure in the second direction, a first epitaxial pattern on at least one side of the gate structure, on the both sides of the dielectric wall structure in the second direction, connected to the plurality of channel layers, and having an epitaxial trench that is adjacent to the plurality of channel layers in the first direction, a second epitaxial pattern including a pattern portion filling the epitaxial trench and a protrusion portion protruding upward from the epitaxial trench in the third direction, and a third epitaxial pattern surrounding side surfaces and an upper surface of the second epitaxial pattern in the second direction, where the pattern portion has a width that decreases towards the substrate in the third direction, the protrusion portion has a width that increases towards the substrate in the third direction, an upper surface of the pattern portion contacts a first channel layer that is an uppermost channel layer of the plurality of channel layers in the second direction, and an upper surface of the protrusion portion is spaced apart from the first channel layer in the second direction.

According to an aspect of an example embodiment, a method of manufacturing a semiconductor device may include alternately stacking sacrificial layers and channel layers on a substrate, partially removing the sacrificial layers, the channel layers, and the substrate to form an active structure including an active region, forming a dielectric wall structure between adjacent active structures, forming a sacrificial gate structure, partially removing the sacrificial layers and channel layers that are exposed form the sacrificial gate structures to form recess regions, forming epitaxial patterns in the recess regions, forming an interlayer insulating layer and removing the sacrificial gate structures and sacrificial layers, forming a gate structure, and selectively removing portions of an outer dielectric wall and source/drain regions. The sacrificial layers and channel layers may be formed by performing an epitaxial growth process from the stacked structure, the dielectric wall structure may be formed by sequentially depositing insulating materials on the substrate and the active structure, and removing the insulating material from the remaining portion except for a portion between the adjacent active structures,

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a semiconductor device according to one or more embodiments;

FIG. 2 is a plan view illustrating a semiconductor device according to one or more embodiments;

FIGS. 3A to 3C are cross-sectional views illustrating a semiconductor device according to one or more embodiments;

FIGS. 4 and 5 are enlarged views illustrating a semiconductor device according to one or more embodiments;

FIGS. 6 to 9 are enlarged views illustrating a semiconductor device according to one or more embodiments;

FIGS. 10 and 11 are enlarged views illustrating a semiconductor device according to one or more embodiments;

FIGS. 12A, 13A, 14A, 15A, 16A, 17A and 18A are views illustrating a method of manufacturing a semiconductor device according to one or more embodiments;

FIGS. 12B, 13B, 14B, 15B, 16B, 17B and 18B are views illustrating a method of manufacturing a semiconductor device according to one or more embodiments; and

FIGS. 12C, 13C, 14C, 15C, 16C, 17C and 18C are drawings illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Unless otherwise specifically stated, in this specification, terms such as “upper”, “an upper surface”, “lower”, “a lower surface”, “a side surface”, and the like are based on the drawings, and may actually vary depending on a direction in which a component is arranged.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, ordinal numbers such as “first”, “second”, “third”, and the like may be used as labels for specific elements, steps, directions, and the like to distinguish various elements, steps, directions, etc. from each other. Terms not described using “first”, “second”, etc. in the specification may still be referred to as “first” or “second” in the claims. In addition, terms referenced by a specific ordinal number (e.g., “first” in a particular claim) may be described elsewhere with a different ordinal number (e.g., “second” in the specification or another claim).

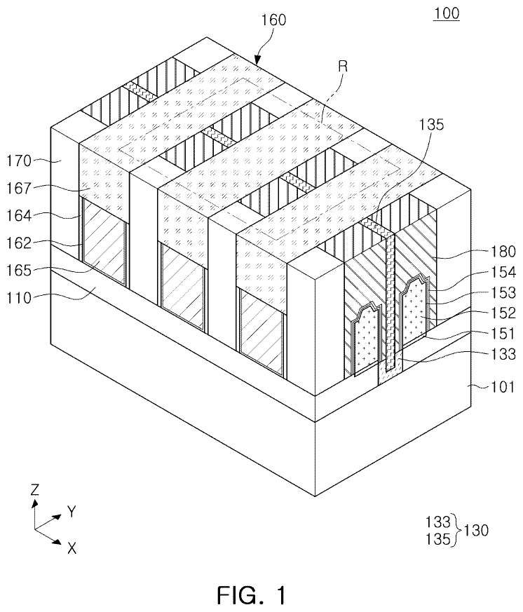

FIG. 1 is a perspective view illustrating a semiconductor device according to one or more embodiments.

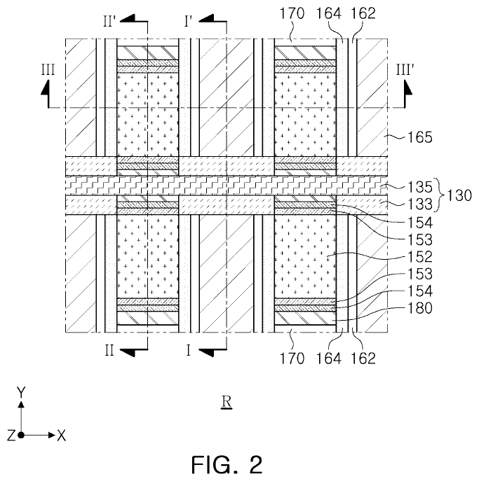

FIG. 2 is a plan view illustrating a semiconductor device according to one or more embodiments.

FIG. 2 illustrates a plan view of region ‘R’ of the semiconductor device of FIG. 1 but below the upper surface of the device of FIG. 1. That is, FIG. 2 is a cross-sectional top view of the semiconductor device of FIG. 1 correspond to region R but below the upper surface of the semiconductor device of FIG. 1.

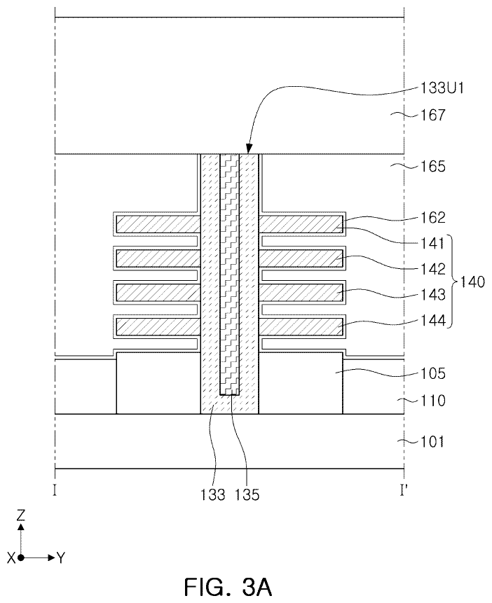

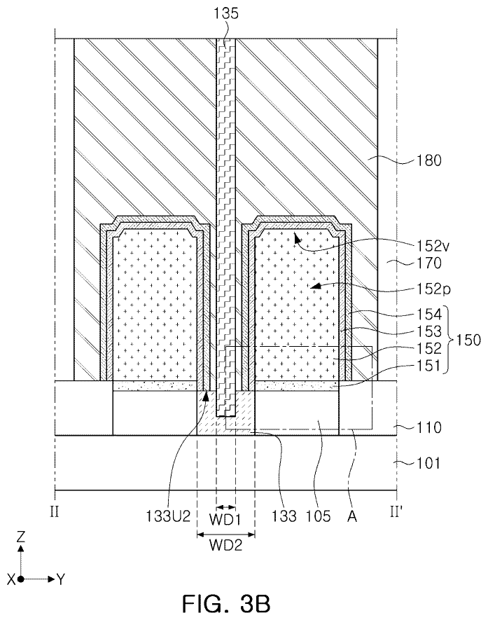

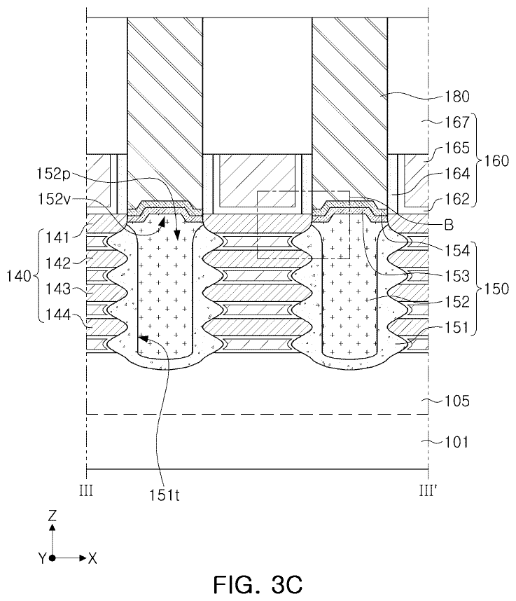

FIGS. 3A to 3C are cross-sectional views illustrating a semiconductor device according to one or more embodiments.

FIG. 3A illustrates a cross-section of the semiconductor device of FIG. 2 taken along line I-I′. FIG. 3B illustrates a cross-section of the semiconductor device of FIG. 2 taken along line II-II′. FIG. 3C illustrates a cross-section of the semiconductor device of FIG. 2 taken along line III-III′.

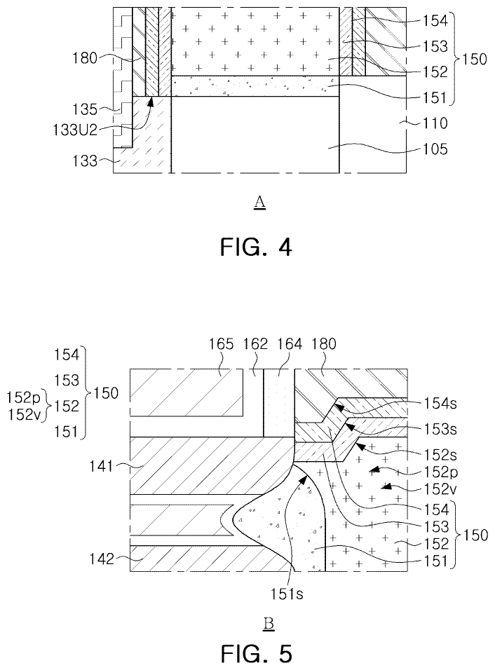

FIG. 4 is an enlarged view illustrating a semiconductor device according to one or more embodiments. FIG. 4 is an enlarged view of region ‘A’of FIG. 3B.

FIG. 5 is an enlarged view illustrating a semiconductor device according to one or more embodiments. FIG. 5 is an enlarged view of region ‘B’of FIG. 3C.

Referring to FIGS. 1 to 5, the semiconductor device 100 may include a substrate 101 including active regions 105, a dielectric wall structure 130 disposed between adjacent active regions 105, channel structures 140 including first to fourth channel layers 141, 142, 143 and 144 vertically spaced apart from each other on the active regions 105, gate structures 160 extending across the active regions 105 and each including a gate electrode 165, source/drain regions 150 contacting the channel structures 140, and metal patterns 180 connected to the source/drain regions 150. The semiconductor device 100 may further include a device isolation layer 110 and an interlayer insulating layer 170.

Referring to FIG. 3A, in the semiconductor device 100, the active region 105 may have a fin structure, and the gate electrode 165 may be disposed between the active region 105 and the channel structure 140, between the first to fourth channel layers 141, 142, 143 and 144 of the channel structure 140, and on the channel structure 140. Accordingly, the semiconductor device 100 may include transistors of a Multi Bridge Channel field effect transistor (FET) (MBCFET™) structure, which is a gate-all-around type field effect transistor (GAAFET).

The substrate 101 may have an upper surface extending in an X-direction and a Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

In one or more embodiments, the substrate 101 and the active region 105 may be an insulating layer formed integrally with the device isolation layer 110. In this case, the insulating layer may be a layer formed by removing and/or oxidizing the substrate 101 and the active region 105 formed of a semiconductor material during the manufacturing process. In one or more embodiments, the substrate 101 may include an oxide, a nitride, or a combination thereof.

The substrate 101 may include an active region 105 disposed thereon. The active region 105 may be defined by the device isolation layer 110 in the substrate 101, and may be disposed to extend in a first direction, such as the X-direction. The active region 105 may partially protrude from the device isolation layer 110, so that an upper surface of the active region 105 may be positioned on a level higher than a level of an upper surface of the device isolation layer 110. The active region 105 may be formed as a portion of the substrate 101, and may include an epitaxial layer grown from the substrate 101. However, the active region 105 may be partially recessed on both side surfaces of the gate structure 160 to form recessed regions, and the source/drain regions 150 may be disposed in the recessed regions.

In one or more embodiments, the upper surface of the substrate 101 may include a {100} crystal plane. For example, the upper surface of the substrate 101 may be one of a (−1 0 0) plane, a (0 1 0) plane, a (0 −1 0) plane, a (0 0 1) plane, and a (0 0 −1) plane.

In one or more embodiments, the active region 105 may or may not include a well region including impurities. For example, in the case of a p-type transistor (pFET), the well region may include n-type impurities such as phosphorus (P), arsenic (As), or antimony (Sb), and in the case of an n-type transistor (nFET), the well region may include p-type impurities such as boron (B), gallium (Ga), or indium (In). The well region may be positioned, for example, at a predetermined depth from the upper surface of the active region 105. In one or more embodiments, a pair of active regions 105 disposed on both side surfaces of the dielectric wall structure 130 may include the same p-type or n-type impurities. In one or more embodiments, a pair of active regions 105 disposed on both side surfaces of the dielectric wall structure 130 may include impurities of different conductivity types.

The device isolation layer 110 may define the active region 105 in the substrate 101. The device isolation layer 110 may be formed, for example, by a shallow trench isolation (STI) process. The device isolation layer 110 may expose the upper surface of the active region 105, and may also expose an upper portion of the active region 105. In one or more embodiments, the device isolation layer 110 may have a curved upper surface so that it has a higher level towards the active region 105. The device isolation layer 110 may be formed of an insulating material. The device isolation layer 110 may be formed of an oxide, a nitride, or a combination thereof, for example.

The dielectric wall structure 130 may extend in a first direction, for example, the X-direction, on the substrate 101. The dielectric wall structure 130 may extend in the first direction (e.g., the X-direction) between adjacent active regions 105. The dielectric wall structure 130 may penetrate the gate structure 160 to separate the gate electrode 165, and may separate the source/drain regions 150 disposed on both side surfaces of the dielectric wall structure 130. A lowermost surface of the dielectric wall structure 130 may contact the upper surface of the substrate 101. An uppermost surface of the dielectric wall structure 130 may be coplanar or substantially coplanar with an upper surface of a gate capping layer 167.

The dielectric wall structure 130 may include an outer dielectric wall 133 and an inner dielectric wall 135.

The outer dielectric wall 133 may extend in a first direction (e.g., X-direction) on the substrate 101. The outer dielectric wall 133 may be spaced apart from the gate electrode 165 by a gate dielectric layer 162. That is, the outer dielectric wall 133 may separate the gate electrode 165. In one or more embodiments, the outer dielectric wall 133 may have a side surface inclined so as to narrow towards the substrate 101, but embodiments are not limited thereto.

Referring to FIGS. 3A and 3B, the outer dielectric wall 133 may include a first upper surface 133U1 and a second upper surface 133U2. The first upper surface 133U1 may be an upper surface of a portion of the outer dielectric wall 133 and may have a substantially the same height as an upper surface of the inner dielectric wall 135. The second upper surface 133U2 may be an upper surface of a portion of the outer dielectric wall 133 that is below the source/drain region 150 and extends in the second direction (e.g., Y-direction), and may contact the source/drain region 150 and the metal pattern 180. The first upper surface 133U1 may be positioned on a level higher than the second upper surface 133U2. The first upper surface 133U1 may be positioned on substantially the same level as an upper surface of the gate electrode 165. The second upper surface 133U2 may be positioned on substantially the same level as a lower surface of the source/drain region 150.

Referring to FIG. 3A, the outer dielectric wall 133 may extend between the gate structure 160 and a side surface of the inner dielectric wall 135. The first upper surface 133U1, which is an upper surface of the outer dielectric wall 133 intersecting the gate structure 160, may have the same height as the upper surface of the inner dielectric wall 135.

Referring to FIG. 3B, the outer dielectric wall 133 may surround a portion of the side surface of the inner dielectric wall 135 and the lower surface of the inner dielectric wall 135. Side surfaces of the outer dielectric wall 133 in the second direction (e.g., Y-direction) may contact the active regions 105. In addition, the outer dielectric wall 133 may include regions that are overlapped by the source/drain regions 150 in a third direction (e.g., Z-direction). For example, a portion of the second upper surface 133U2 of the outer dielectric wall 133 may contact the source/drain region 150, and therefore portions of the source/drain regions 150 may overlap the dielectric wall 133 in the third direction (e.g., the Z-direction).

Referring to FIG. 2, the dielectric wall structure 130 may have a width at a portion overlapping or adjacent to the gate structure 160 in the second direction (e.g., the Y-direction) greater than a width at a portion overlapping or adjacent to the metal pattern 180 in the second direction (e.g., the Y-direction). For example, the width at the portion overlapping or adjacent to the gate structure 160 may have a value of a width of the outer dielectric wall 133 plus a width of the inner dielectric wall 135, and the width at the portion overlapping or adjacent to the metal pattern 180 may be a width of the inner dielectric wall 135. In other words, the outer dielectric wall 133 and the inner dielectric wall 135 may be provided adjacent to the gate structure 160, and only the inner dielectric wall 135 may be provided adjacent to the metal pattern 180.

The outer dielectric wall 133 may include an insulating material. For example, the outer dielectric wall 133 may include a nitride. In one or more embodiments, the outer dielectric wall 133 may include silicon nitride (SiN).

The inner dielectric wall 135 may be disposed on the outer dielectric wall 133, and may extend in the first direction (e.g., X-direction) on the substrate 101. The inner dielectric wall 135 may be spaced apart from the substrate 101 and the gate electrode 165 by the outer dielectric wall 133.

The inner dielectric wall 135 may separate the gate electrode 165 and the metal patterns 180. The upper surface of the inner dielectric wall 135 may be positioned on a level equal to or higher than the upper surface of the gate electrode 165. The upper surface of the inner dielectric wall 135 may be positioned on a level higher than upper surfaces of the source/drain regions 150. The lower surface of the inner dielectric wall 135 may be positioned on a level lower than the second upper surface 133U2 of the outer dielectric wall 133. The upper surface of the inner dielectric wall 135 and the first upper surface 133U1 of the outer dielectric wall 133 may form an uppermost surface of the dielectric wall structure 130, and may be coplanar or substantially coplanar with the upper surface of the gate capping layer 167.

When viewed in plan as in FIG. 2, the inner dielectric wall 135 may overlap the source/drain region 150 in the second direction (e.g., Y-direction), and a portion of the inner dielectric wall 135 may overlap the source/drain region 150 in the second direction (e.g., Y-direction). The source/drain regions 150 and the metal patterns 180 may be disposed on both side surfaces of the inner dielectric wall 135.

The inner dielectric wall 135 may include an insulating material. In one or more embodiments, the inner dielectric wall 135 may include a material different from that of the outer dielectric wall 133. In one or more embodiments, the inner dielectric wall 135 may include an oxide, a nitride, or a combination thereof. In one or more embodiments, the inner dielectric wall 135 may include at least one of, for example, SiO, SiN, SiCN, SiOC, SiON or SiOCN, or a combination thereof.

The lower surface of the inner dielectric wall 135 may have a first width WD1. In one or more embodiments, the inner dielectric wall 135 may have a side surface inclined so as to become narrow towards the substrate 101, but embodiments are not limited thereto. The first width WD1 may refer to a width of the inner dielectric wall 135 in the second direction, for example, the Y-direction. In one or more embodiments, the first width WD1 may be between 5 nm and 35 nm. If the width of the lower surface of the inner dielectric wall 135 is 5 nm or less, it may be difficult to electrically isolate the gate electrode 165 and the source/drain regions 150 disposed on both sides of the dielectric wall structure 130. Accordingly, it may be difficult to improve the reliability of the semiconductor device 100. If the width of the lower surface of the inner dielectric wall 135 is 35 nm or more, it may be difficult to improve a degree of integration as a size of a region occupied by the semiconductor device 100 increases.

A lower surface of the outer dielectric wall 133 may have a second width WD2. The second width WD2 of the outer dielectric wall 133 may refer to a width of the outer dielectric wall 133 in the second direction, for example, the Y-direction. Thicknesses of the inner dielectric wall 135 and the outer dielectric wall 133 may each be between 5 nm and 35 nm, respectively. A difference between the second width WD2 and the first width WD1 may be between about 10 nm and about 70 nm. That is, the second width WD2 may be between 15 nm and 105 nm.

If the second width WD2 of the lower surface of the outer dielectric wall 133 is 15 nm or less, it may be difficult to electrically isolate the gate electrode 165 and the source/drain regions 150 disposed on both sides of the dielectric wall structure 130. Accordingly, it may be difficult to improve the reliability of the semiconductor device 100. If the second width WD2 of the lower surface of the outer dielectric wall 133 is 105 nm or more, it may be difficult to improve a degree of integration as a size of a region occupied by the semiconductor device 100 increases.

The semiconductor device 100 including such a dielectric wall structure 130 may include the outer dielectric wall 133 that is selectively removed in a region in which the source/drain region 150 overlaps the dielectric wall structure 130 in the second direction (e.g., Y-direction) when viewed in plan such as in FIG. 2. As a result, the metal pattern 180 may be disposed in the region in which the removed outer dielectric wall 133 was disposed. In addition, the inner dielectric wall 135 may stably separate the gate electrode 165, and may allow adjacent source/drain regions 150 to be stably separated from each other. A description related thereto will be specifically described in a description of a manufacturing method described below. Accordingly, a semiconductor device having improved reliability and integration may be provided.

Referring to FIGS. 2 and 3C, the gate structures 160 may be disposed on the active region 105 and the channel structures 140 to extend in the second direction, for example, the Y-direction. Functional channel regions of transistors may be formed in the active region 105 and/or the channel structures 140 intersecting the gate electrodes 165 of the gate structures 160. Each of the gate structures 160 may include the gate electrode 165, gate dielectric layers 162 between the gate electrode 165 and the first to fourth channel layers 141, 142, 143 and 144, gate spacer layers 164 on side surfaces of the gate electrode 165, and the gate capping layer 167 extending in the second direction (e.g., the Y-direction) on the gate electrode 165.

The gate dielectric layers 162 may be disposed between the active region 105 and the gate electrode 165, between the channel structure 140 and the gate electrode 165, and between the dielectric wall structure 130 and the gate electrode 165, and may be disposed to cover at least a portion of surfaces of the gate electrode 165. For example, the gate dielectric layers 162 may be disposed to surround all surfaces except an uppermost surface of the gate electrode 165. The gate dielectric layers 162 may extend between the gate electrode 165 and the gate spacer layers 164, but embodiments are not limited thereto.

The gate dielectric layers 162 may include an oxide, a nitride, or a high-κ material. The high-κ material may refer to a dielectric material having a dielectric constant higher than that of a silicon oxide (SiO₂) film. The high-κ material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). According to embodiments, the gate dielectric layer 162 may be formed as a multilayer film.

The gate electrode 165 may be disposed to fill spaces between the first to fourth channel layers 141, 142, 143 and 144 on the active region 105 and extend onto the channel structure 140. The gate electrode 165 may be spaced apart from the first to fourth channel layers 141, 142, 143 and 144 by the gate dielectric layers 162.

The gate electrode 165 may include a conductive material, and may include, for example, a metal nitride such as a titanium nitride (TiN), a tantalum nitride (TaN), or a tungsten nitride (WN), and/or a metal material such as aluminum (Al), tungsten (W), or molybdenum (Mo), or a semiconductor material such as doped polysilicon. According to embodiments, the gate electrode 165 may be composed of two or more layers.

The gate spacer layers 164 may be disposed on both side surfaces of the gate electrode 165 on the channel structure 140. The gate spacer layers 164 may insulate the source/drain regions 150 and the gate electrode 165. The gate spacer layers 164 may be formed as a multilayer structure, according to one or more embodiments.

The gate spacer layers 164 may be formed of at least one of an oxide, a nitride, and an oxynitride, and may be formed of a low-κ film. The gate spacer layers 164 may include, for example, at least one of SiO, SiN, SiCN, SiOC, SiON, or SiOCN. In one or more embodiments, the gate spacer layers 164 may include the same material as the inner dielectric wall 135.

The gate capping layer 167 may extend in the second direction, for example, the Y-direction, on the gate electrode 165 and the gate spacer layers 164. The gate capping layer 167 may include at least one of an oxide, a nitride, and an oxynitride.

The channel structures 140 may be disposed on the active region 105 in regions in which the active region 105 contacts the gate structures 160. Each of the channel structures 140 may include the first to fourth channel layers 141, 142, 143 and 144, which are a plurality of channel layers spaced apart from each other in the third direction, for example, the Z-direction, and may be parallel to the upper surface of the substrate 101. The first to fourth channel layers 141, 142, 143 and 144 may be sequentially disposed from an upper portion thereof, and the first channel layer 141 may be an uppermost channel layer. The channel structures 140 may be connected to the source/drain regions 150.

The channel structures 140 may have a width which is the same as or similar to a width of the gate structures 160 in the X-direction, and may have a width which is the same as or less than a width of the active region 105 in the Y-direction. In a cross-section in the Y-direction, among the first to fourth channel layers 141, 142, 143 and 144, a channel layer disposed below another may have a width that is equal to or greater than a width of the channel layer disposed above. The number or shape of the channel layers forming one channel structure 140 may vary in embodiments. For example, one channel structure 140 may include three channel layers, two channel layers, or five or more channel layers. In addition, the channel structures 140 may include regions in which thicknesses decrease towards a first epitaxial pattern 151 in the first direction (e.g., the X-direction).

The channel structures 140 may be formed of a semiconductor material, and may include, for example, at least one of silicon (Si), silicon germanium (SiGe), or germanium (Ge). The channel structures 140 may be formed of, for example, the same material as the active region 105. In one or more embodiments, the channel structures 140 may include an impurity region positioned adjacent to the source/drain regions 150.

The source/drain regions 150 may be disposed in recessed regions in which upper portions of the active regions 105 on both surfaces of the gate structure 160 are partially recessed. The source/drain regions 150 may be disposed on both side surfaces of the dielectric wall structure 130. The recessed regions may extend along side surfaces of the channel structures 140 and side surfaces of the gate dielectric layers 162. The source/drain regions 150 may be disposed to cover side surfaces of each of the first to fourth channel layers 141, 142, 143 and 144 of the channel structures 140 in the X-direction. Upper surfaces of the source/drain regions 150 may be positioned on the same level as or a level higher than an upper surface of the first channel layer 141 of the channel structures 140, and the level may be variously modified. In one or more embodiments, side surfaces of the source/drain regions 150 may have a curvature according to the first to fourth channel layers 141, 142, 143 and 144 and the gate structure 160. However, a specific shape of the side surfaces of the source/drain regions 150 may be variously modified.

The source/drain regions 150 may include a semiconductor material, for example, at least one of silicon (Si) or germanium (Ge), and may further include dopants. For example, when the semiconductor device 100 is a pFET, the dopants may be at least one of boron (B), gallium (Ga) or indium (In).

Referring to FIG. 3B, the source/drain regions 150 may include the first epitaxial pattern 151, a second epitaxial pattern 152, a third epitaxial pattern 153, and a silicide pattern 154.

The first epitaxial pattern 151 may be formed on the upper surface of the active region 105 and at least one side surface (e.g., both side surfaces) of the gate structure 160. In addition, the first epitaxial pattern 151 may be disposed on a side surface of the dielectric wall structure 130 and a side surface of the gate structure 160 to be connected to the channel structures 140. For example, the first epitaxial pattern 151 may be connected to each of the first to fourth channel layers 141, 142, 143 and 144 penetrating the gate structure 160. The first epitaxial pattern 151 may be electrically isolated from the gate electrode 165 by the gate dielectric layer 162 and/or the gate spacer layers 164. The first epitaxial pattern 151 may include an epitaxial layer. For example, the first epitaxial pattern 151 may be formed from the active region 105 by an epitaxial growth method.

A width of the first epitaxial pattern 151 in the first direction (e.g., X-direction) is shown to be constant only in a height direction (i.e., the third direction (e.g., Z-direction)), but this is only an example. Depending on characteristics of an etching process (or recess process) performed on the active region 105 to form the first epitaxial pattern 151, the width of the first epitaxial pattern 151 in the first direction (e.g., X-direction) may decrease towards the substrate 101.

Referring to FIG. 3B, a width of the first epitaxial pattern 151 in the second direction (e.g., Y-direction) may be the same as a width of the active region 105. The width of the first epitaxial pattern 151 in the second direction (e.g., Y-direction) is shown to be constant only in the height direction (i.e., the third direction (e.g., Z-direction)), but this is only an example. If the width of the active region 105 decreases away from the substrate 101, the width of the first epitaxial pattern 151 in the second direction (e.g., Y-direction) may also decrease away from the substrate 101.

The first epitaxial pattern 151 may include an epitaxial trench 151t therein. For example, as illustrated in FIG. 3C, the epitaxial trench 151t may be defined by at least a portion of an upper surface of the first epitaxial pattern 151. The epitaxial trench 151t may be adjacent to the channel structures 140 in the first direction (e.g., X-direction). The epitaxial trench 151t may extend in the second direction (e.g., Y-direction). For example, the first epitaxial pattern 151 may have a ‘U’ shape in a cross-section intersecting the second direction (e.g., Y-direction). In one or more embodiments, the epitaxial trench 151t may be a deep trench adjacent to the first to fourth channel layers 141, 142, 143 and 144 in the first direction (e.g., X-direction). For example, a lower surface of the epitaxial trench 151t may be lower than an upper surface of the fourth channel layer 144, and an upper surface of the epitaxial trench 151t may be higher than a lower surface of the first channel layer 141. The upper surface of the first epitaxial pattern 151 may include a first inclined plane 151s. The first inclined plane 151s may be adjacent to the gate structure 160. In addition, a height of the first inclined plane 151s may decrease away from the gate structure 160.

The epitaxial trench 151t may extend downward from the first inclined plane 151s towards the substrate 101. A width of the epitaxial trench 151t in the first direction (e.g., X-direction) is shown to be constant only in a height direction (i.e., the third direction (e.g., Z-direction)), but this is only an example. In the case in which the width of the first epitaxial pattern 151 in the first direction (e.g., X-direction) decreases towards the substrate 101, the width of the epitaxial trench 151t in the first direction (e.g., X-direction) may also decrease towards the substrate 101.

The second epitaxial pattern 152 may be formed on the first epitaxial pattern 151. The second epitaxial pattern 152 may be adjacent to a plurality of channel layers in the first direction (e.g., X-direction) on the first epitaxial pattern 151. The second epitaxial pattern 152 may be connected to the first epitaxial pattern 151. As illustrated in FIG. 3C, the second epitaxial pattern 152 may fill the epitaxial trench 151t of the first epitaxial pattern 151. For example, with reference to the upper surface of the substrate 101, a height of an upper surface of the second epitaxial pattern 152 may be greater than a height of the upper portion of the first epitaxial trench 151t, whereby a contact area between the first epitaxial pattern 151 and the second epitaxial pattern 152 may be increased, so that a contact resistance between the first epitaxial pattern 151 and the second epitaxial pattern 152 may be improved.

A width of the second epitaxial pattern 152 in the first direction (e.g., X-direction) may not be constant in a height direction (i.e., the third direction (e.g., Z-direction)). The second epitaxial pattern 152 may be formed on the epitaxial trench 151t in the first direction (e.g., X-direction) decreasing towards the substrate 101, so that the width of the second epitaxial pattern 152 in the first direction (e.g., X-direction) may also decrease towards the substrate 101.

Referring to FIG. 3B, a width of the second epitaxial pattern 152 in the second direction (e.g., Y-direction) may be equal to or greater than the width of the active region 105. The width of the second epitaxial pattern 152 in the second direction (e.g., Y-direction) may increase away from the gate structures 160.

Referring to FIGS. 3B and 3C, the second epitaxial pattern 152 may include a pattern portion 152p filling an epitaxial trench 151t of the first epitaxial pattern 151 and a protrusion portion 152v protruding upwardly from the pattern portion 152p.

The pattern portion 152p may have a width decreasing towards the substrate 101 in the third direction (e.g., the Z-direction), and the protrusion portion 152v may have a width increasing towards the substrate 101 in the third direction (e.g., the Z-direction). A width of an upper surface of the pattern portion 152p may be greater than a width of a lower surface of the protrusion portion 152v. In this case, as a contact area between the source/drain region 150 and the metal pattern 180 increases, ability to control the source/drain region 150 of the metal pattern may be further enhanced.

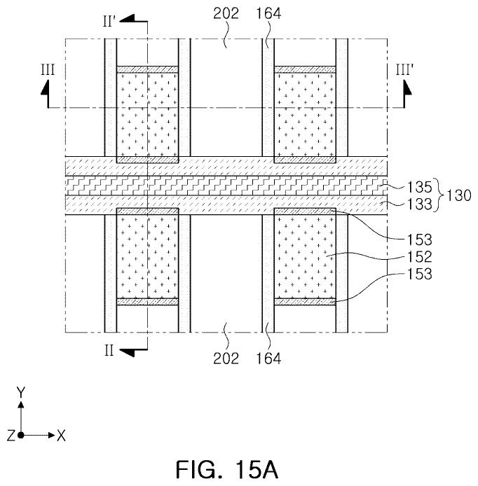

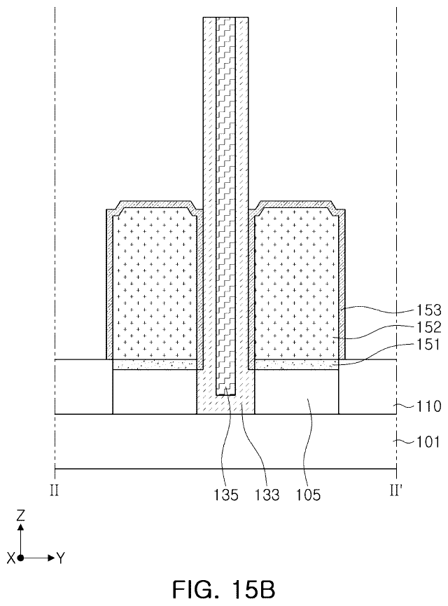

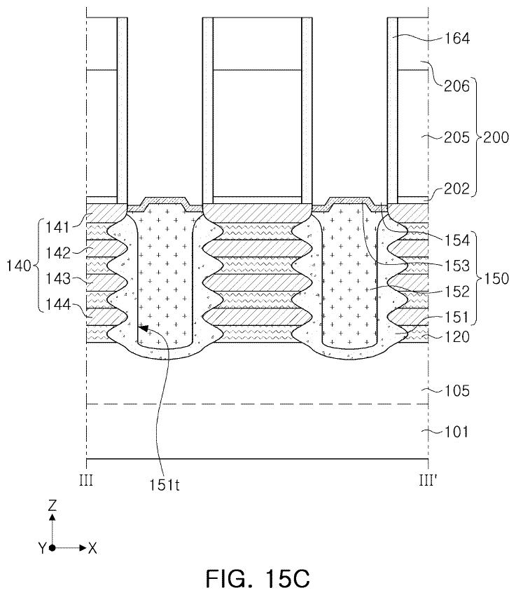

The upper surface of the pattern portion 152p may be adjacent to the first channel layer 141 positioned in an uppermost portion of the plurality of channel layers in the second direction (e.g., the Y-direction), and the upper surface of the protrusion portion 152v may be spaced apart from the first channel layer 141 in the second direction (e.g., the Y-direction). For example, the upper surface of the pattern portion 152p around the protrusion portion 152v may be positioned on the same level as or a level higher than a point at which the first channel layer 141 contacts the first epitaxial pattern 151, and may extend toward the first channel layer 141 in the second direction (e.g., Y-direction). Since the upper surface of the pattern portion 152p is surrounded by the third epitaxial pattern 153, a portion of a lower surface of the third epitaxial pattern 153 may contact the upper surface of the pattern portion 152p and be adjacent to the first channel layer 141. In addition, since the upper surface of the protrusion portion 152v is surrounded by the third epitaxial pattern 153, a portion of the lower surface of the third epitaxial pattern 153 may contact the upper surface of the protrusion portion 152v and spaced apart from the first channel layer 141. Thereby, since the first and third epitaxial patterns 151 and 153 protect the second epitaxial pattern 152 having a high concentration of germanium (Ge), the second epitaxial pattern 152 may be prevented from being partially removed when the sacrificial gate structure (200 in FIG. 15A) is removed in a process of forming the gate electrode 165.

In one or more embodiments, the upper surface of the pattern portion 152p may include a {100} crystal plane. For example, the upper surface of the pattern portion 152p may be one of a (−1 0 0) plane, a (0 1 0) plane, a (0 −1 0) plane, a (0 0 1) plane, and a (0 0 −1) plane.

In one or more embodiments, a side surface of the protrusion portion 152v may include a second inclined plane 152s. The second inclined plane 152s may have a height increasing away from the gate structures 160. In one or more embodiments, the second inclined plane 152s may include a {111} crystal plane. For example, the second inclined plane 152s may be one of a (1 1 1) plane, a (1 1 −1) plane, a (1 −1 1) plane, a (1 −1 −1) plane, a (−1 1 1) plane, a (−1 1 −1) plane, a (−1 −1 1) plane, and a (−1 −1 −1) plane.

The third epitaxial pattern 153 may be formed on the second epitaxial pattern 152. The third epitaxial pattern 153 may be connected to the second epitaxial pattern 152. The third epitaxial pattern 153 may surround an outer peripheral surface of the second epitaxial pattern 152. For example, as illustrated in FIG. 3B, the third epitaxial pattern 153 may cover side and upper surfaces of the second epitaxial pattern 152 in the second direction (e.g., Y-direction). In addition, the third epitaxial pattern 153 may be positioned between the second epitaxial pattern 152 and the dielectric wall structure 130. Furthermore, the third epitaxial pattern 153 may cover the protrusion portion 152v of the second epitaxial pattern 152.

In one or more embodiments, the third epitaxial pattern 153 may include a third inclined plane 153s along the second inclined plane 152s of the protrusion portion 152v of the second epitaxial pattern 152. The third inclined plane 153s may have a height increasing away from the gate structure 160. In one or more embodiments, the third inclined plane 153s may include a {111} crystal plane. For example, the third inclined plane 153s may be one of a (1 1 1) plane, a (1 1 −1) plane, a (1 −1 1) plane, a (1 −1 −1) plane, a (−1 1 1) plane, a (−1 1 −1) plane, a (−1 −1 1) plane, and a (−1 −1 −1) plane.

The silicide pattern 154 may be formed on the third epitaxial pattern 153. The silicide pattern 154 may be connected to the third epitaxial pattern 153. The silicide pattern 154 may surround an outer peripheral surface of the third epitaxial pattern 153. For example, as illustrated in FIG. 3B, the silicide pattern 154 may cover side and upper surfaces of the third epitaxial pattern 153 in the second direction (e.g., Y-direction). In addition, the silicide pattern 154 may be positioned between the third epitaxial pattern 153 and the dielectric wall structure 130.

In one or more embodiments, the silicide pattern 154 may include a fourth inclined surface 154s along the third inclined surface 153s of the third epitaxial pattern 153. The fourth inclined surface 154s may have a height increasing away from the gate structure 160. In one or more embodiments, the fourth inclined surface 154s may include a {111} crystal plane. For example, the fourth inclined surface 154 s may be one of a (1 1 1) plane, a (1 1 −1) plane, a (1 −1 1) plane, a (1 −1 −1) plane, a (−1 1 1) plane, a (−1 1 −1) plane, a (−1 −1 1) plane, and a (−1 −1 −1) plane.

The source/drain regions 150 may include a semiconductor material, for example at least one of silicon (Si) or germanium (Ge), and may further include dopants. In one or more embodiments, a pair of source/drain regions 150 disposed on both side surfaces of one dielectric wall structure 130 may include dopants of the same conductivity type. In one or more embodiments, a pair of source/drain regions 150 disposed on both side surfaces of one dielectric wall structure 130 may include dopants of different conductivity types.

For example, in the case of a p-type transistor (pFET), the first epitaxial pattern 151 and the second epitaxial pattern 152 may have different concentrations of silicon-germanium (SiGe). The first epitaxial pattern 151 may include silicon-germanium (SiGe) doped with p-type impurities. For example, the p-type impurities may be at least one of boron (B), gallium (Ga), or indium (In). In one or more embodiments, the first epitaxial pattern 151 may be SiGe doped with B. In one or more embodiments, the first epitaxial pattern 151 may have a first concentration of germanium (Ge), and the second epitaxial pattern 152 may have a second concentration of germanium (Ge), greater than the first concentration. For example, the first concentration may be between 0 at % and 5 at %, and the second concentration may be between 20 at % and 60 at %.

The first epitaxial pattern 151 and the third epitaxial pattern 153 may have the same concentration of silicon-germanium (SiGe). The third epitaxial pattern 153 may include silicon-germanium (SiGe) doped with p-type impurities. For example, the p-type impurities may be at least one of boron (B), gallium (Ga), or indium (In). In one or more embodiments, the third epitaxial pattern 153 may be SiGe doped with B. In one or more embodiments, the third epitaxial pattern 153 may have a third concentration of germanium (Ge). For example, the third concentration may be between 0 at % to 5 at %. Thereby, the second epitaxial pattern 152 having a high concentration of germanium (Ge) may be protected. Since the first and third epitaxial patterns 151 and 153 protect the second epitaxial pattern 152, the second epitaxial pattern 152 may be prevented from being partially removed when the sacrificial gate structure (200 in FIG. 15A) is removed in the process of forming the gate electrode 165, whereby a reliability of semiconductor devices may be enhanced.

For example, in the case of an n-type transistor (nFET), the first epitaxial pattern 151 and the second epitaxial pattern 152 may have different concentrations of silicon-germanium (SiGe). The first epitaxial pattern 151 may include silicon-germanium (SiGe) doped with n-type impurities. For example, the n-type impurity may be at least one of phosphorus (P), arsenic (As), or antimony (Sb). In one or more embodiments, the first epitaxial pattern 151 may have a first concentration of germanium (Ge), and the second epitaxial pattern 152 may have a second concentration of germanium (Ge), greater than the first concentration. For example, the first concentration may be between 0 at % and 5 at %, and the second concentration may be between 20 at % and 60 at %.

The first epitaxial pattern 151 and the third epitaxial pattern 153 may have the same concentration. The third epitaxial pattern 153 may include silicon-germanium (SiGe) doped with n-type impurities. For example, the n-type impurities may be at least one of phosphorus (P), arsenic (As), or antimony (Sb). In one or more embodiments, the third epitaxial pattern 153 may have a third concentration of germanium (Ge). For example, the third concentration may be between 0 at % and 5 at %. Thereby, the second epitaxial pattern 152 having a high concentration of germanium (Ge) may be protected. Since the first and third epitaxial patterns 151 and 153 protect the second epitaxial pattern 152, the second epitaxial pattern 152 may be prevented from being partially removed when the sacrificial gate structure (200 of FIG. 15A) is removed in the process of forming the gate electrode 165, whereby a reliability of semiconductor devices may be enhanced.

The metal patterns 180 may penetrate the interlayer insulating layer 170 to be connected to the source/drain regions 150, and may apply an electrical signal to the source/drain regions 150. The metal patterns 180 may include a region contacting the gate spacer layers 164 in the first direction (e.g., X-direction).

Referring to FIG. 4, the metal patterns 180 may extend from an upper portion of the metal patterns 180 to below the upper surface of the first epitaxial pattern 151. The metal pattern 180 may be connected to the silicide pattern 154. The metal pattern 180 may surround an outer peripheral surface of the source/drain region 150. For example, as illustrated in FIG. 3B, the metal pattern 180 may cover side and upper surfaces of the silicide pattern 154 in the second direction (e.g., Y-direction). In addition, the metal pattern 180 may be positioned between the silicide pattern 154 and the dielectric wall structure 130.

Referring to FIG. 4, the metal patterns 180 may have side surfaces extending along side surfaces of the inner dielectric wall 135 of the dielectric wall structure 130. In addition, the metal pattern 180 may fill at least a portion of a space between the dielectric wall structure 130 and the source/drain region 150. For example, the third epitaxial pattern 153, the silicide pattern 154, and the metal pattern 180 may be positioned in this order between the second epitaxial pattern 152 and the dielectric wall structure 130, whereby a contact area between the metal pattern 180 and the source/drain region 150 may be increased, thereby improving the contact resistance for the source/drain region 150.

Furthermore, referring to FIG. 3B, a bottom of the third epitaxial pattern 153 may contact a side surface of the first epitaxial pattern 151, and the third epitaxial pattern 153, the silicide pattern 154, and the metal pattern 180 may extend between the first epitaxial pattern 151 and the dielectric wall structure 130. Thereby, since the first and third epitaxial patterns 151 and 153 protect the second epitaxial pattern 152, the second epitaxial pattern 152 may be prevented from being partially removed when the sacrificial gate structure (200 in FIG. 15A) is removed in the process of forming the gate electrode 165, whereby a reliability of semiconductor devices may be enhanced.

The interlayer insulating layer 170 may be disposed to cover the source/drain regions 150, the gate structures 160, and the metal pattern 180 on the device isolation layer 110. The interlayer insulating layer 170 may include at least one of an oxide, a nitride, or an oxynitride, and may include, for example, a low-κ material. According to one or more embodiments, the interlayer insulating layer 170 may include a plurality of insulating layers.

The semiconductor device 100 may be packaged by flipping the structures of FIGS. 3A to 3C upside down so that the substrate 101 is positioned on top, but the packaging form of the semiconductor device 100 is not limited thereto. The semiconductor device 100 may have enhanced reliability and integration by including the dielectric wall structure 130 separating the gate electrode 165 and the source/drain regions 150.

In the description of embodiments below, any description overlapping with the description described above with reference to FIGS. 1 to 5 will be omitted.

FIGS. 6 to 9 are enlarged views illustrating semiconductor devices according to one or more embodiments.

FIGS. 6 to 9 illustrate enlarged views corresponding to FIG. 4, which are enlarged views of region ‘A’of FIG. 3B.

Referring to FIG. 6, the second upper surface 133U2 of the outer dielectric wall 133 may be positioned between a level of a lower surface and a level of the upper surface of the first epitaxial pattern 151. In one or more embodiments, the second upper surface 133U2 of the outer dielectric wall 133 may be positioned on a level higher than the lower surface of the first epitaxial pattern 151. The third epitaxial pattern 153, the silicide pattern 154, and the metal pattern 180 may extend between the first epitaxial pattern 151 and the inner dielectric wall 135. Accordingly, lower surfaces of the third epitaxial pattern 153, the silicide pattern 154, and the metal pattern 180 positioned between the inner dielectric wall 135 and the second epitaxial pattern 152 may also be positioned on a level higher than the lower surface of the first epitaxial pattern 151. In one or more embodiments, the outer dielectric wall 133 may be removed only up to a level higher than the lower surface of the first epitaxial pattern 151 in a process of being selectively removed during the process.

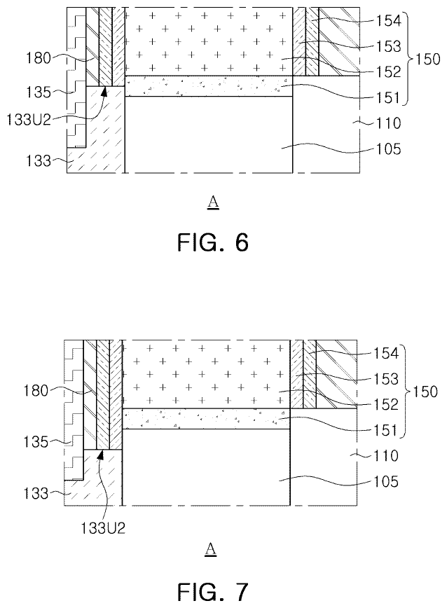

Referring to FIG. 7, the second upper surface 133U2 of the outer dielectric wall 133 may be lower than that shown in FIG. 6. In one or more embodiments, the second upper surface 133U2 of the outer dielectric wall 133 may be positioned on a level lower than the lower surface of the first epitaxial pattern 151. The third epitaxial pattern 153, the silicide pattern 154, and the metal pattern 180 may extend between the first epitaxial pattern 151 and the inner dielectric wall 135, and may extend between the active region 105 and the inner dielectric wall 135. Accordingly, the lower surfaces of the third epitaxial pattern 153, the silicide pattern 154, and the metal pattern 180 positioned between the inner dielectric wall 135 and the second epitaxial pattern 152 may also be positioned on a level lower than the lower surface of the first epitaxial pattern 151. In one or more embodiments, the outer dielectric wall 133 may be removed up to a level lower than the lower surface of the first epitaxial pattern 151 in a process of being selectively removed during the process.

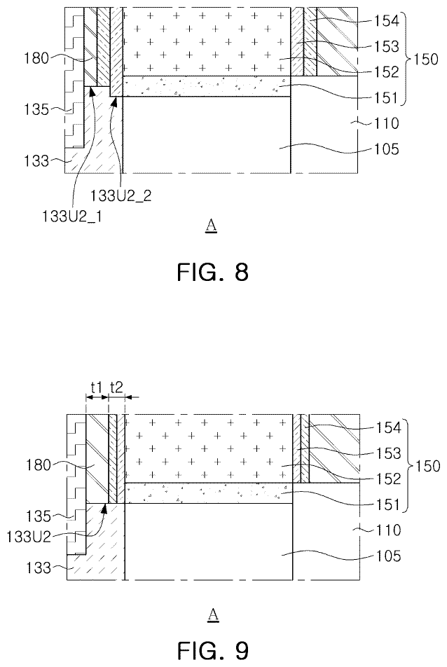

Referring to FIG. 8, the lower surfaces of the silicide pattern 154 and the metal pattern 180 may be positioned on a level between the lower surface and the upper surface of the first epitaxial pattern 151, and the lower surface of the third epitaxial pattern 153 may be on substantially the same level as the level of the lower surface of the first epitaxial pattern 151. In one or more embodiments, the third epitaxial pattern 153 may be formed to contact (e.g., remain in contact with) a side surface of the first epitaxial pattern 151 in a process of selectively removing the outer dielectric wall 133 and forming the third epitaxial pattern 153 during the process. Additionally, in a process of removing the outer dielectric wall 133 and forming the silicide pattern 154 and the metal pattern 180, the outer dielectric wall 133 may be removed up to a level higher than the lower surfaces of the first epitaxial pattern 151 and the third epitaxial pattern 153, and the silicide pattern 154 and the metal pattern 180 may be formed. In this case, the silicide pattern 154 and the metal pattern 180 may be formed on a level higher than the lower surface of the first epitaxial pattern 151.

Referring to FIG. 9, a thickness of the metal pattern 180 positioned between the inner dielectric wall 135 and the silicide pattern 154 may be greater than that of the embodiment of FIG. 4 in the second direction (e.g., Y-direction). In one or more embodiments, the thickness of the metal pattern 180 may be greater than a thickness of the silicide pattern 154. The thickness of the metal pattern 180 may refer to a thickness between a surface contacting the inner dielectric wall 135 and a surface contacting the silicide pattern 154 in the second direction (e.g., Y-direction). In one or more embodiments, the thickness of the metal pattern 180 may be greater than each of thicknesses of the third epitaxial pattern 153 and the silicide pattern 154 positioned between the inner dielectric wall 135 and the second epitaxial pattern 152. In addition, it may be greater than the sum of the thicknesses of the third epitaxial pattern 153 and the silicide pattern 154. As the thickness of the metal pattern 180 increases, a sheet resistance of the metal pattern 180 may be improved. Accordingly, an electrical resistance inside the metal pattern 180 may be improved.

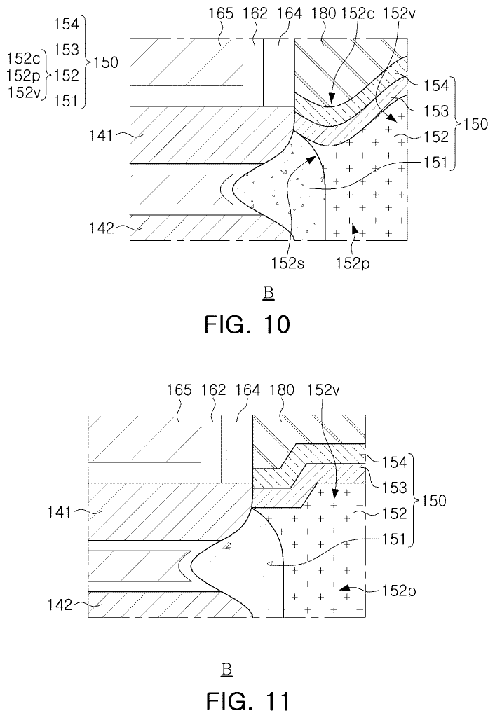

FIGS. 10 and 11 are enlarged views illustrating semiconductor devices according to one or more embodiments. FIGS. 10 and 11 illustrate enlarged views corresponding to FIG. 5, which are enlarged views of region ‘B’of FIG. 3B.

Referring to FIG. 10, the second epitaxial pattern 152 may further include a concave portion 152c having a shape that surrounds the protrusion portion 152v. The concave portion 152c may be continuously disposed along a perimeter of the protrusion portion 152v (e.g., the concave portion 152c may have a first horizontal width, and the protrusion portion 152v, which may correspond to a convex portion, may have a second horizontal width that is greater than the first horizontal width). The concave portion 152c may have a width less than that of the protrusion portion 152v. Accordingly, the third epitaxial pattern 153 and the silicide pattern 154 may also have a concave shape along the concave portion 152c of the second epitaxial pattern.

Referring to FIG. 11, the first epitaxial pattern 151 and the third epitaxial pattern 153 may be connected in the third direction (e.g., in the Z-direction). The first channel layer 141 may contact the first epitaxial pattern 151 and the third epitaxial pattern 153. The first epitaxial pattern 151 may be connected to the third epitaxial pattern 153 in the third direction (e.g., in the Z-direction). Accordingly, the first and third epitaxial patterns 151 and 153 may be disposed between the second epitaxial pattern 152 and the first channel layer 141. The pattern portion 152p of the second epitaxial pattern 152 may be spaced apart from the first channel layer 141 in the first direction (e.g., X-direction).

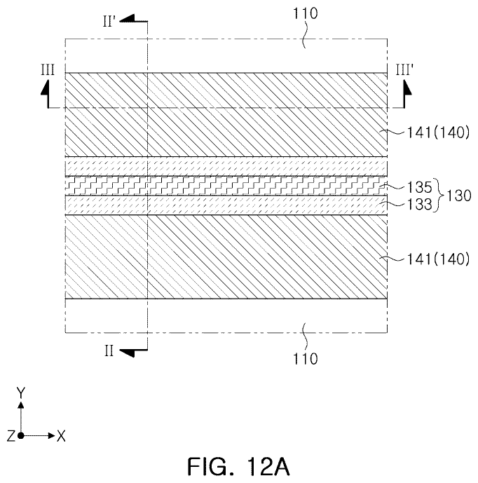

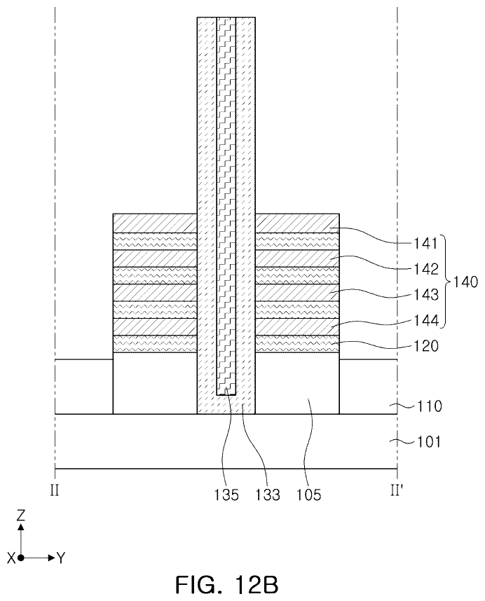

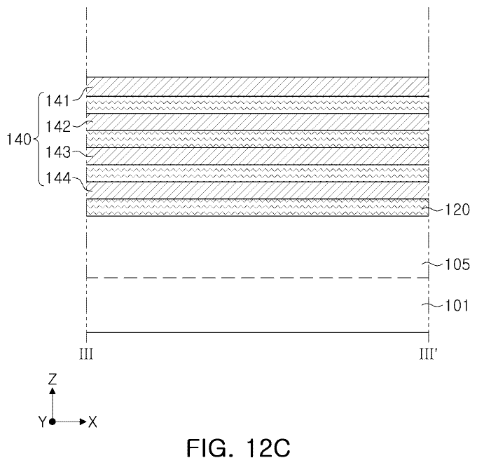

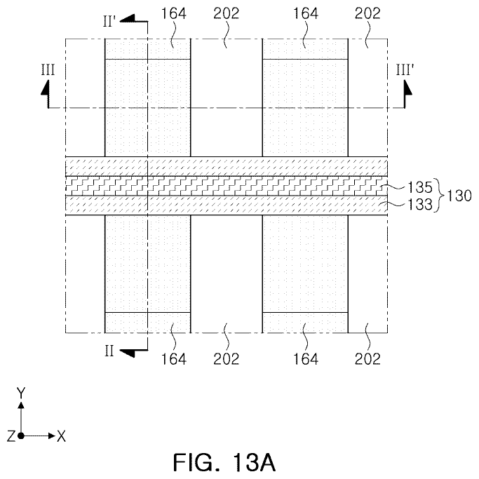

FIGS. 12A, 13A, 14A, 15A, 16A, 17A and 18A are views illustrating a method of manufacturing a semiconductor device according to one or more embodiments;

FIGS. 12B, 13B, 14B, 15B, 16B, 17B and 18B are views illustrating a method of manufacturing a semiconductor device according to one or more embodiments; and

FIGS. 12C, 13C, 14C, 15C, 16C, 17C and 18C are drawings illustrating a method of manufacturing a semiconductor device according to one or more embodiments.

In the description of FIGS. 12A to 18C, it will be described that the process sequence proceeds in the order of the drawing numbers, and the drawings with the same number illustrate the same process. For example, FIGS. 12A, 12B, and 12C illustrate the same processes.

Referring to FIGS. 12A to 12C, sacrificial layers 120 and first to fourth channel layers 141, 142, 143 and 144 may be alternately stacked on a substrate 101.

The sacrificial layers 120 may be layers that are replaced with gate dielectric layers 162 and gate electrodes 165 below the first channel layer 141 via a subsequent process, as illustrated in FIGS. 3A and 3C. The sacrificial layers 120 may be formed of a material having etching selectivity with respect to the first to fourth channel layers 141, 142, 143 and 144, respectively. The first to fourth channel layers 141, 142, 143 and 144 may include a different material from the sacrificial layers 120. The sacrificial layers 120 and the first to fourth channel layers 141, 142, 143 and 144 may include a semiconductor material including, such as at least one of silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143 and 144 may include silicon (Si).

The sacrificial layers 120 and the first to fourth channel layers 141, 142, 143 and 144 may be formed by performing an epitaxial growth process from the stacked structure. The number of layers of the channel layers alternately stacked with the sacrificial layers 120 may vary in embodiments.

Then, the sacrificial layers 120, the first to fourth channel layers 141, 142, 143 and 144, and the substrate 101 may be partially removed to form an active structure including an active region 105. The active structure may include the active region 105, the sacrificial layers 120, and the first to fourth channel layers 141, 142, 143 and 144. The active structure be formed in a line shape extending in one direction, for example, an X-direction, and may be formed spaced apart from the active structure adjacent in a Y-direction. Side surfaces of the active structures in the Y-direction may be coplanar with each other, and may be positioned on a straight line.

Then, a dielectric wall structure 130 may be formed between adjacent active structures. The dielectric wall structure 130 may be formed by sequentially depositing insulating materials on the substrate 101 and the active structure, and then removing the insulating material from the remaining portion except for a portion between the adjacent active structures. In one or more embodiments, a nitride to form an outer dielectric wall 133 may be deposited to fill a space between the adjacent active structures, then an oxide to form an inner dielectric wall 135 may be deposited between the outer dielectric walls, and the deposited nitride and oxide may be partially removed to form the outer dielectric wall 133 and the inner dielectric wall 135. The dielectric wall structure 130 may be formed in a form extending in a first direction, for example, the X-direction, between the adjacent active structures.

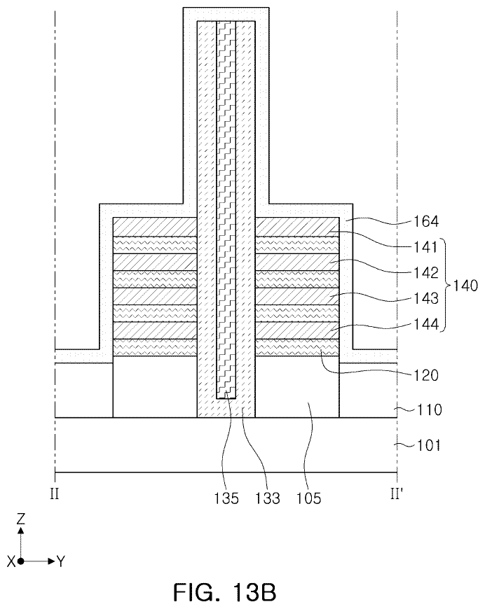

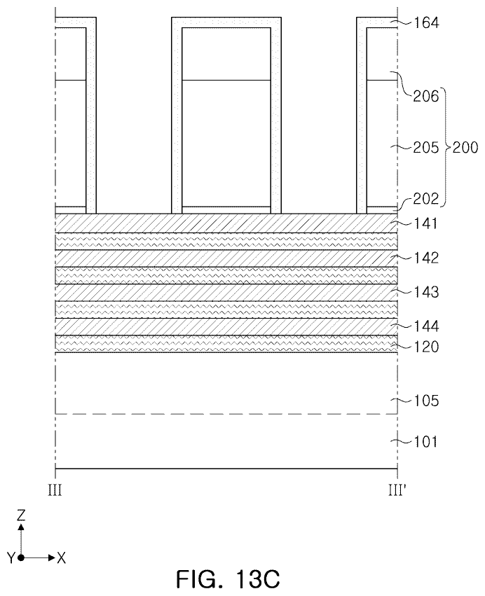

Referring to FIGS. 13A to 13C, sacrificial gate structures 200 may be formed on the active structure.

The sacrificial gate structure 200 may be a sacrificial structure formed in a region in which the gate dielectric layer 162 and the gate electrode 165 will be disposed on the channel structures 140 via a subsequent process, as illustrated in FIGS. 3A and 3C. The sacrificial gate structure 200 may not be formed in a region in which a source/drain region 150 will be formed, as illustrated in FIG. 3B. The sacrificial gate structure 200 may have a line shape extending in one direction while intersecting the active structure. The sacrificial gate structures 200 may extend in the Y-direction, for example, and may be spaced apart from each other in the X-direction.

The sacrificial gate structure 200 may include first and second sacrificial gate layers 202 and 205 and a mask pattern layer 206 which are sequentially stacked. The first and second sacrificial gate layers 202 and 205 may be patterned using the mask pattern layer 206. The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

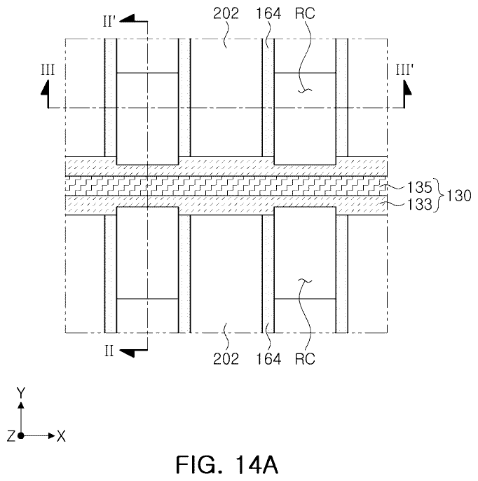

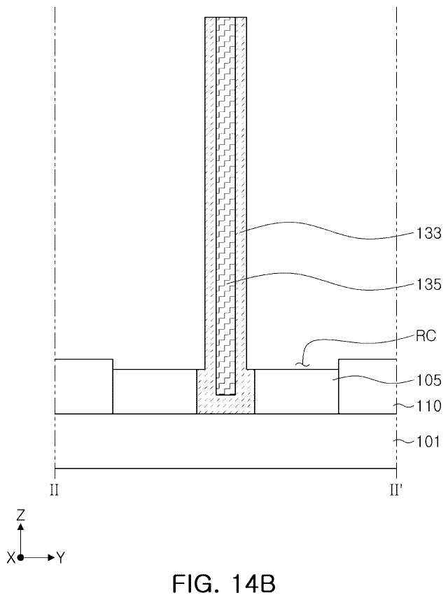

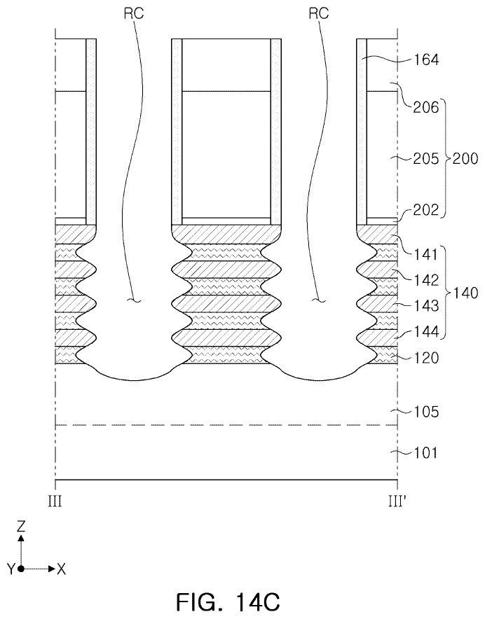

Referring to FIGS. 14A to 14C, the sacrificial layers 120 and the first to fourth channel layers 141, 142, 143 and 144 exposed from the sacrificial gate structures 200 may be partially removed to form recess regions RC.

Using the sacrificial gate structures 200 and the gate spacer layers 164 as a mask, a portion of the exposed sacrificial layers 120 and a portion of the first to fourth channel layers 141, 142, 143 and 144 may be removed to form recess regions RC, whereby the first to fourth channel layers 141, 142, 143 and 144 may form channel structures 140 having a limited length in the X-direction. In one or more embodiments, side surfaces of the sacrificial layers 120 may be selectively etched with respect to the channel structures 140 by a wet etching process, and removed to a predetermined depth from the side surfaces in the X-direction. Accordingly, the sacrificial layers 120 may have inwardly concave side surfaces due to side etching as described above. A specific shape of the side surfaces of the sacrificial layers 120 is not limited to that illustrated in FIG. 14C.

Referring to FIGS. 14A and 14B, the outer dielectric wall 133 may be selectively removed. The outer dielectric wall 133 may include a material having etch selectivity with respect to the materials included in the sacrificial layers 120 and the first to fourth channel layers 141, 142, 143 and 144, and only a portion of the outer dielectric wall 133 may be selectively removed without loss of the sacrificial layers 120 and the first to fourth channel layers 141, 142, 143 and 144. For example, the outer dielectric wall 133 may be composed of a nitride, and nitric acid may be used during the etching process. In one or more embodiments, the selective removal of a portion of the outer dielectric wall 133 may be by a wet etching process or an isotropic dry etching process.

Referring to FIGS. 15A to 15C, first to third epitaxial patterns 151, 152 and 153 may be formed in the recess regions RC.

The first epitaxial pattern 151 may fill a portion of the recess regions RC. The first epitaxial pattern 151 may be formed by an epitaxial growth method using the active region 105 as a seed layer, whereby the first epitaxial pattern 151 connected to the active region 105 may be formed.

Referring to FIGS. 15A and 15C, the first epitaxial pattern 151 may include an epitaxial trench 151t. For example, a thickness of the first epitaxial pattern 151 may be formed so as not to completely fill the recess regions RC. Thereby, the first epitaxial pattern 151 having a ‘U’ shape in a cross-section intersecting the second direction (e.g., Y-direction) may be formed.

A second epitaxial pattern 152 may be formed on an upper surface of the first epitaxial pattern 151. The second epitaxial pattern 152 may include an epitaxial layer. The second epitaxial pattern 152 may be connected to the first epitaxial pattern 151. The second epitaxial pattern 152 may fill the epitaxial trench 151t of the first epitaxial pattern 151. For example, with reference to an upper surface of the substrate 101, a height of an upper surface of the second epitaxial pattern 152 may be greater than a height of an upper portion of a first epitaxial trench 151t. A width of the second epitaxial pattern 152 in the first direction (e.g., X-direction) may not be constant in a height direction (i.e., the third direction (e.g., Z-direction)).

A third epitaxial pattern 153 may be formed on the second epitaxial pattern 152. The third epitaxial pattern 153 may be connected to the second epitaxial pattern 152. The third epitaxial pattern 153 may surround an outer surface of the second epitaxial pattern 152. The third epitaxial pattern 153 may cover side and upper surfaces of the second epitaxial pattern 152 in the second direction (e.g., Y-direction).

Referring to FIGS. 15A to 15C, the third epitaxial pattern 153 may fill a space in which a selectively removed outer dielectric wall 133 existed. In addition, the third epitaxial pattern 153 may be positioned between the second epitaxial pattern 152 and the outer dielectric wall 133 that is not removed.

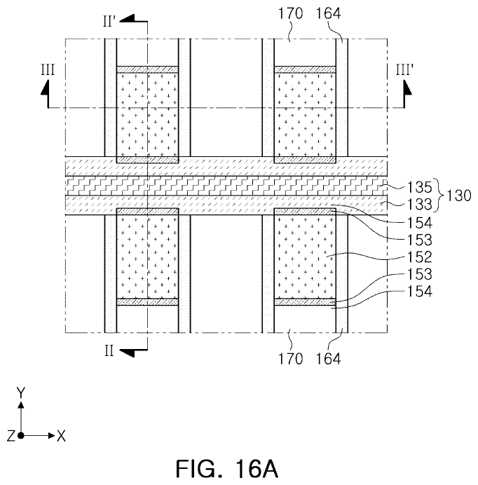

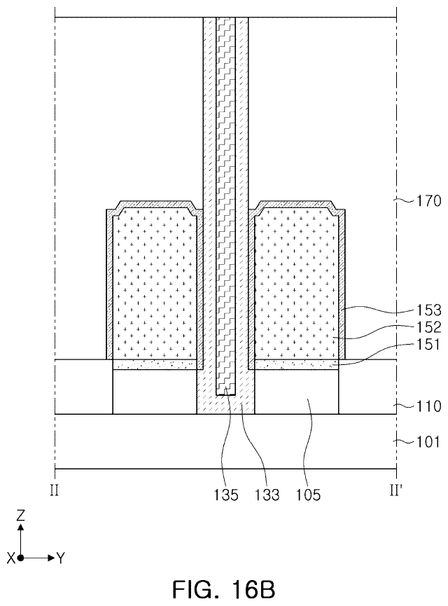

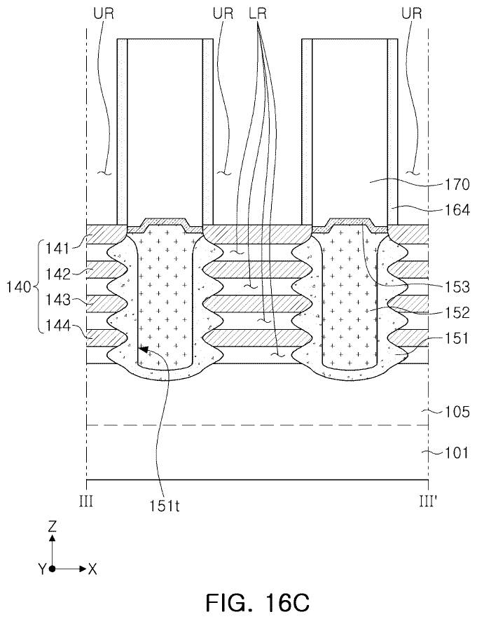

Referring to FIGS. 16A to 16C, an interlayer insulating layer 170 may be partially formed, and the sacrificial gate structures 200 and the sacrificial layers 120 may be removed.

The interlayer insulating layer 170 may be formed by forming an insulating film covering the sacrificial gate structures 200 and the source/drain regions 150 and performing a planarization process.

The sacrificial gate structures 200 and the sacrificial layers 120 may be selectively removed with respect to the gate spacer layers 164, the interlayer insulating layer 170, and the channel structures 140. First, the sacrificial gate structures 200 may be removed to form upper gap regions UR, and then the sacrificial layers 120 exposed through the upper gap regions UR may be removed to form lower gap regions LR. For example, when the sacrificial layers 120 include silicon germanium (SiGe) and the channel structures 140 include silicon (Si), the sacrificial layers 120 may be selectively removed with respect to the channel structures 140 and the source/drain regions 150 by performing a wet etching process.

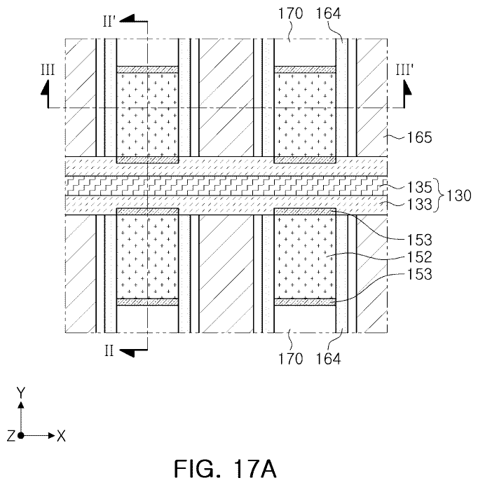

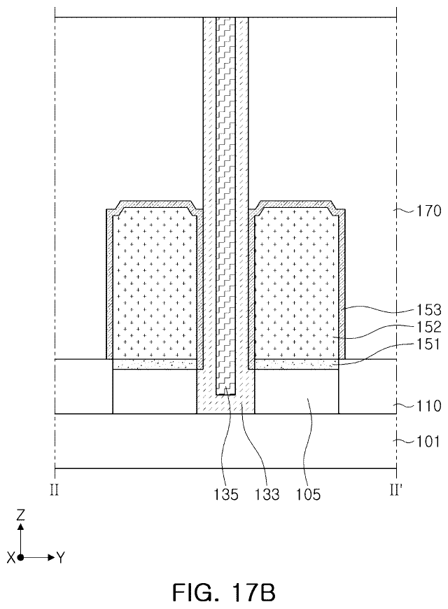

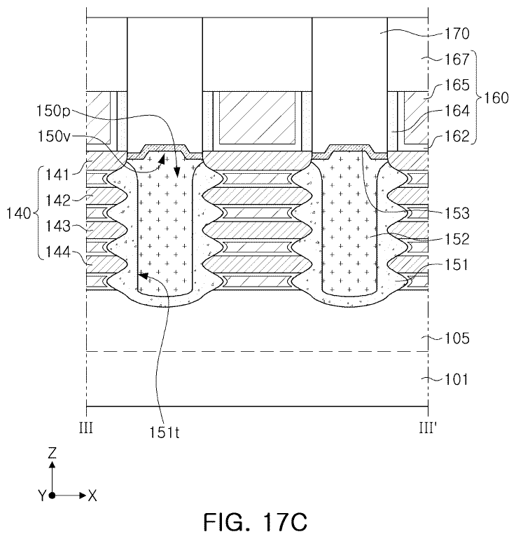

Referring to FIGS. 16A to 16C and FIGS. 17A to 17C, the gate dielectric layers 162, the gate electrode 165, and a gate capping layer 167 may be formed, thereby forming a gate structure 160. The gate dielectric layers 162 and the gate electrode 165 may be formed to fill the upper gap regions UR and the lower gap regions LR. The gate dielectric layers 162 may be formed to conformally cover inner surfaces of the upper gap regions UR and the lower gap regions LR. The gate electrode 165 may be formed to completely fill the upper gap regions UR and the lower gap regions LR, and then removed from the upper gap regions UR to a predetermined depth together with the gate dielectric layers 162 and the gate spacer layers 164. The gate capping layer 167 may be formed to extend in the first direction (e.g., X-direction) on the gate electrode 165 and the dielectric wall structure 130.

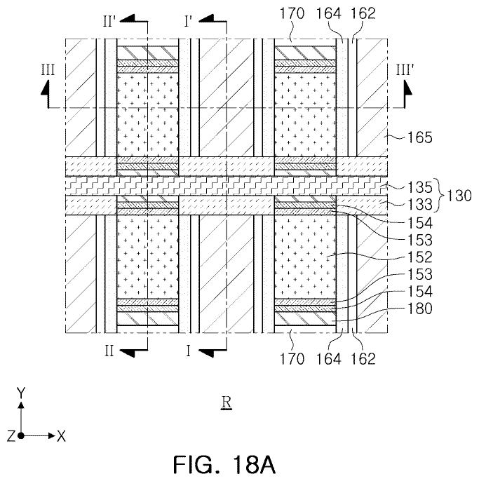

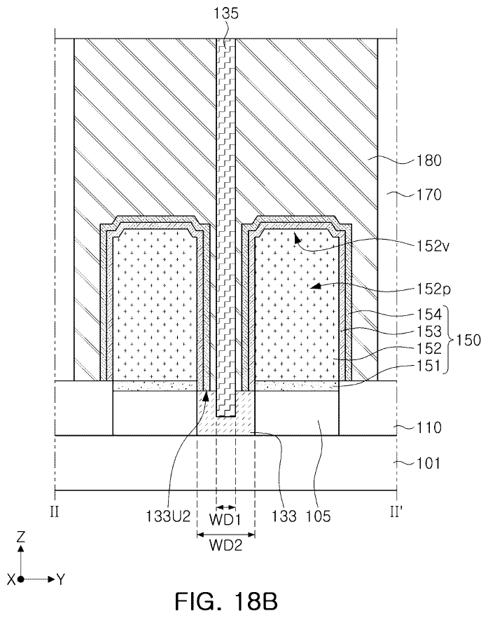

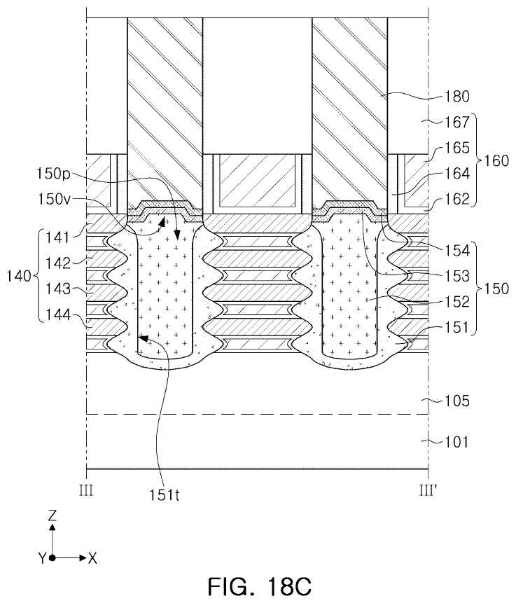

Referring to FIGS. 18A to 18C, the outer dielectric wall 133 of the source/drain region 150 may be selectively removed. In addition, a portion of the interlayer insulating layer 170 may be removed and a metal pattern 180 may be formed. Thereafter, referring to FIGS. 3B and 3C together, the interlayer insulating layer 170 positioned in a space where the metal pattern 180 is to be placed may be removed. As a portion of the interlayer insulating layer is removed, the third epitaxial pattern 153 may be exposed. As a portion of the interlayer insulating layer is removed, the outer dielectric wall 133 contacting the third epitaxial pattern 153 may be exposed.

Next, the outer dielectric wall 133 adjacent to the source/drain region 150 in the second direction (e.g., Y-direction) may be removed. The outer dielectric wall 133 may include a material having an etch selectivity with respect to materials included in the gate structures 160, the third epitaxial pattern 153, and the inner dielectric wall 135, and only a portion of the outer dielectric wall 133 may be selectively removed without loss of the gate structures 160 and the third epitaxial pattern 153. For example, the outer dielectric wall 133 may be composed of a nitride, and nitric acid may be used during the etching process. In one or more embodiments, selective removal of a portion of the outer dielectric wall 133 may be performed by a wet etching or isotropic dry etching process. At this time, a portion of the inner dielectric wall 135 may also be etched, but since the inner dielectric wall 135 has a thickness of at least 5 nm, the source/drain regions 150 on both side surfaces of the inner dielectric wall 135 may still be separated.

Next, the metal pattern 180 and a silicide pattern 154 may be formed in a region in which the outer dielectric wall 133 was removed.

The metal pattern 180 may be formed in a space from in which the interlayer insulating layer 170 was removed. The metal pattern 180 may be formed around the source/drain region 150. The metal pattern 180 may surround an outer peripheral surface of the source/drain region 150. For example, the metal pattern 180 may cover side and upper surfaces of the third epitaxial pattern 153 in the second direction (e.g., the Y-direction). In addition, the metal pattern 180 may be positioned between the third epitaxial pattern 153 and the dielectric wall structure 130. The metal pattern 180 may have side surfaces extending along the side surfaces of the inner dielectric wall 135 of the dielectric wall structure 130. In addition, the metal pattern 180 may fill at least a portion of a space between the dielectric wall structure 130 and the source/drain region 150.

The silicide pattern 154 may be formed on a surface with which the metal pattern 180 and the third epitaxial pattern 153 come into contact. The silicide pattern 154 may be formed on the third epitaxial pattern 153. The silicide pattern 154 may be connected to the third epitaxial pattern 153. The silicide pattern 154 may surround the outer surface of the third epitaxial pattern 153. For example, as illustrated in FIG. 3B, the silicide pattern 154 may cover the side and upper surfaces of the third epitaxial pattern 153 in the second direction (e.g., Y-direction). In addition, the silicide pattern 154 may be connected to the metal pattern 180. The silicide pattern 154 may be positioned between the third epitaxial pattern 153 and the metal pattern 180.

Accordingly, the semiconductor device 100 of FIGS. 1 to 5 may be manufactured. Metal interconnections electrically connected to the metal patterns 180 may be formed on the metal patterns 180.

According to one or more embodiments, a semiconductor device may be provided in which a dielectric wall structure is configured as an outer dielectric wall and an inner dielectric wall, and the outer dielectric wall is optionally removed, and a metal pattern is formed between the dielectric wall structure and the source/drain regions, thereby improving a resistance to current flowing through the metal pattern and enhancing a controllability of source/drain regions.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a substrate comprising an active region extending in a first direction;
a gate structure on the substrate and extending in a second direction intersecting the first direction;
a plurality of channel layers on the active region, spaced apart from each other in a third direction perpendicular to an upper surface of the substrate, and surrounded by the gate structure;
a dielectric wall structure on one side of the active region, extending in the first direction and penetrating the gate structure;
a first epitaxial pattern on a side surface of the dielectric wall structure and connected to the plurality of channel layers;
a second epitaxial pattern on the first epitaxial pattern;
a third epitaxial pattern surrounding side surfaces and an upper surface of the second epitaxial pattern in the second direction;
a silicide pattern surrounding side surfaces and an upper surface of the third epitaxial pattern in the second direction; and
a metal pattern surrounding side surfaces and an upper surface of the silicide pattern in the second direction,
wherein the third epitaxial pattern, the silicide pattern, and the metal pattern are between the second epitaxial pattern and the dielectric wall structure.

2. The semiconductor device of claim 1, wherein the third epitaxial pattern contacts a side surface of the first epitaxial pattern, and
wherein the metal pattern contacts the side surface of the dielectric wall structure.

3. The semiconductor device of claim 1, wherein the dielectric wall structure comprises a first portion adjacent to the gate structure in the second direction that has a first width, and a second portion adjacent to the metal pattern in the second direction that has a second width, and
wherein the second width is less than the first width.

4. The semiconductor device of claim 1, wherein a thickness of the metal pattern between the dielectric wall structure and the silicide pattern in the second direction is greater than a thickness of the silicide pattern in the second direction.

5. The semiconductor device of claim 1, wherein each of the plurality of channel layers comprises a region having a thickness that decreases toward the first epitaxial pattern in the first direction.

6. The semiconductor device of claim 1, wherein each of the first epitaxial pattern, the second epitaxial pattern, and the third epitaxial pattern comprise a silicon-germanium compound (SiGe), and
wherein a concentration of germanium (Ge) in the first epitaxial pattern and a concentration of germanium (Ge) in the third epitaxial pattern are less than a concentration of germanium (Ge) in the second epitaxial pattern.

7. The semiconductor device of claim 1, wherein a thickness of the third epitaxial pattern is between 1 nm and 5 nm.

8. The semiconductor device of claim 1, wherein the gate structure comprises:
a gate electrode surrounding the plurality of channel layers; and
gate spacer layers disposed on both side surfaces of the gate electrode in the first direction and above the plurality of channel layers in the third direction, and
wherein the metal pattern comprises a region contacting the gate spacer layers.

9. A semiconductor device, comprising:
a substrate;
a dielectric wall structure on the substrate and extending in a first direction;
active regions extending in the first direction and on both side surfaces of the dielectric wall structure in a second direction intersecting the first direction;
a gate structure on the substrate and extending in the second direction, wherein the dielectric wall structure intersects the gate structure;
a plurality of channel layers on at least one of the active regions, spaced apart from each other in a third direction perpendicular to an upper surface of the substrate, and surrounded by the gate structure;
source/drain regions on at least one side of the gate structure, on both side surfaces of the dielectric wall structure in the second direction, and connected to the plurality of channel layers; and
a metal pattern surrounding both side surfaces and an upper surface of the source/drain regions in the second direction,
wherein the dielectric wall structure comprises an inner dielectric wall, and an outer dielectric wall surrounding a portion of a side surface and a lower surface of the inner dielectric wall that is adjacent to the metal pattern in the second direction,
wherein side surfaces of the outer dielectric wall in the second direction contact the active regions, and
wherein the outer dielectric wall comprises regions adjacent to the source/drain regions in the third direction.

10. The semiconductor device of claim 9, wherein the outer dielectric wall extends between the gate structure and side surfaces of the inner dielectric wall adjacent to the gate structure in the second direction, and
wherein an upper surface of the outer dielectric wall intersecting the gate structure is at a level that is substantially the same as a level of an upper surface of the inner dielectric wall.

11. The semiconductor device of claim 9, wherein an upper surface of the outer dielectric wall is at a level that is lower than levels of lower surfaces of the source/drain regions, and
wherein an upper surface of the inner dielectric wall is at a level that is higher than levels of upper surfaces of the source/drain regions.

12. The semiconductor device of claim 9, wherein the lower surface of the inner dielectric wall has a first width,
wherein a lower surface of the outer dielectric wall has a second width that is greater than the first width,
wherein the first width is between 5 nm to 35 nm, and
wherein a difference between the second width and the first width is between 10 nm to 70 nm.

13. The semiconductor device of claim 9, wherein the outer dielectric wall comprises silicon nitride (SixNy), and
wherein the inner dielectric wall comprises a material that is different from the silicon nitride (SixNy).

14. A semiconductor device, comprising:
a substrate;
a dielectric wall structure on the substrate and extending in a first direction;
a gate structure on the substrate and extending in a second direction that intersects the first direction, wherein the dielectric wall structure intersects the gate structure;
a plurality of channel layers spaced apart from each other in a third direction perpendicular to an upper surface of the substrate, and on both sides of the dielectric wall structure in the second direction;
a first epitaxial pattern on at least one side of the gate structure, on the both sides of the dielectric wall structure in the second direction, connected to the plurality of channel layers, and having an epitaxial trench that is adjacent to the plurality of channel layers in the first direction;
a second epitaxial pattern comprising a pattern portion filling the epitaxial trench and a protrusion portion protruding upward from the epitaxial trench in the third direction; and
a third epitaxial pattern surrounding side surfaces and an upper surface of the second epitaxial pattern in the second direction,
wherein the pattern portion has a width that decreases towards the substrate in the third direction,
wherein the protrusion portion has a width that increases towards the substrate in the third direction,
wherein an upper surface of the pattern portion contacts a first channel layer that is an uppermost channel layer of the plurality of channel layers in the second direction, and
wherein an upper surface of the protrusion portion is spaced apart from the first channel layer in the second direction.

15. The semiconductor device of claim 14, wherein the first channel layer contacts the first epitaxial pattern and the third epitaxial pattern,
wherein the first epitaxial pattern and the third epitaxial pattern are connected in the third direction, and
wherein the pattern portion is spaced apart from the first channel layer by the first epitaxial pattern and the third epitaxial pattern in the first direction.

16. The semiconductor device of claim 14, wherein a width of the upper surface of the pattern portion is greater than a width of a lower surface of the protrusion portion.

17. The semiconductor device of claim 14, wherein the second epitaxial pattern further comprises a concave portion continuously disposed along a perimeter of the protrusion portion, and
wherein the concave portion has a shape that surrounds the protrusion portion.

18. The semiconductor device of claim 14, further comprising:
a metal pattern surrounding side surfaces and an upper surface of the third epitaxial pattern in the second direction,
wherein the metal pattern is between the third epitaxial pattern and the dielectric wall structure.

19. The semiconductor device of claim 14, wherein the upper surface of the pattern portion around the protrusion portion is positioned at a level that is the same as or higher than a level of a point in which the first channel layer contacts the first epitaxial pattern.

20. The semiconductor device of claim 14, wherein a Miller index of the upper surface of the pattern portion is (100), and a Miller index of a side surface of the protrusion portion is (111).
